(19) United States
(12) Patent Application Publication
(10) Pub. No.: US 2006/0208342 A1
(43) Pub. Date: Sep. 21, 2006

(54) Silicon-on-nothing metal oxide semiconductor field effect transistor and method of manufacturing the same

(75) Inventors: Yang-Kyu Choi, Daejeon (KR); Dong-Yoon Jang, Daejeon (KR)

Correspondence Address: REED SMITH, LLP;ATTN: PATENT RECORDS DEPARTMENT, 599 LEXINGTON AVENUE, 29TH FLOOR, NEW YORK, NY, 10022-7650, US

(73) Assignee: Korea Advanced Institute of Science and Technology

(21) Appl. No.: 11/345,052

(22) Filed: Feb. 1, 2006

(30) Foreign Application Priority Data
Mar. 17, 2005 (KR) 10-2005-0022425

(51) Int. Cl. H01L 29/06

(52) U.S. Cl. 257/618

(57) ABSTRACT

The present invention relates to a SON MOSFET and method of manufacturing the same, in which a blister is formed within a silicon substrate, thus improving the disadvantages of a bulk structure and a Silicon-On-Insulator (SOI) structure at the same time. The SON MOSFET according to the present invention comprises isolation insulating films formed at both upper sides of a silicon substrate, a gate insulating film and a gate electrode that are sequentially formed on a surface of the silicon substrate between the isolation insulating films, a source region and a drain region that are formed on the silicon substrate between the gate insulating film and the isolation insulating films, a blister formed within the silicon substrate under the gate insulating film, and a silicon channel, which is surrounded by the blister, the source region and the drain region, within the silicon substrate, wherein the blister is formed of hydrogen or helium ion.

### CROSS-REFERENCE TO RELATED APPLICATION

This Nonprovisional application claims priority under 35 U.S.C. §119(a) on Patent Application No. 10-2005-0022425 filed in Korea on Mar. 17, 2005, the entire contents of which are hereby incorporated by reference.

### BACKGROUND

1. Field of the Invention

The present invention relates to a Silicon-On-Nothing (SON) Metal Oxide Semiconductor Field Effect Transistor (MOSFET) and method of manufacturing the same, and more particularly, to a SON MOSFET and method of manufacturing the same, in which a blister is formed within a silicon substrate, thus improving the disadvantages of a bulk structure and a Silicon-On-Insulator (SOI) structure at the same time.

2. Discussion of Related Art

To lower the price of semiconductor devices and enhance the performance thereof, the semiconductor devices have been integrated in accordance with Moore's Law while being continuously shrunken. Several problems that deteriorate device characteristics arise along with the continuous high integration of the semiconductor devices.

For example, due to the high integration, not only the channel length of the field effect transistor is shrunken to 100 nm or less, but also the electric potential of a channel is controlled by the drain as well as the gate. (The channel length of the field effect transistor is shrunken to 100 nm or less for the high integration. Consequently, the electric potential of a channel is controlled by the drain as well as the gate.) For this reason, there arises a problem, such as a short channel effect in which a high leakage current flows between the source and drain even when the transistor is turned off.

To mitigate problems, a transistor having a dual gate (double gate) or a multiple gate of a 3D structure, instead of a 2D structure in which one gate on a channel controls electric potential of the channel, has been proposed. The 3D-structure transistor is adapted to maximize the ability to control electric potential of a channel through a gate voltage by locating gates on top and bottom surfaces and at both sides of the channel. As the ability to control electric potential of a channel through a gate voltage is increased, the leakage current is reduced. It is thus possible to reduce the short channel effect and fabricate a further miniaturized field effect transistor. The method is, however, disadvantageous in that a manufacturing process is too complicated and control of elements (devices)/process parameters is difficult.

A MOSFET employing the SOI structure in which an insulating film is formed on a silicon substrate and single crystalline silicon is grown on the insulating film has been proposed along with the 3D structure. The SOI MOSFET uses an oxide film (SiO₂) (i.e., burial (buried) type oxide) having a relative dielectric constant of 3.9 as the substrate insulation film in order to improve the performance of semiconductor devices.

FIG. 1 is a cross-sectional view of a SOI MOSFET in the related art.

Referring to FIG. 1, the SOI MOSFET in the related art comprises a silicon substrate 10, a substrate insulation film 30, a source region 20, a drain region 21, a silicon channel 11, a gate insulating film 40 and a gate electrode 50.

In the MOSFET of the SOI structure in the related art, the substrate insulation film 30 is used as shown in FIG. 1. Therefore, an anti-punchthrough effect is high (a punchthrough effect is low) in comparison with the bulk-structure MOSFET, the amount of leakage current, which leaks to the bottom of the silicon channel 11 with the semiconductor device being turned off, is low, and junction capacitance of the junction region between the source/drain and the silicon channel 11 is low. As a result, the short channel effect can be significantly reduced. In addition, the level of integration can be increased since an insulation process between semiconductor devices is simple in comparison with the bulk-structure (bulk structure) MOSFET.

The MOSFET of the SOI structure, which has been proposed to reduce the short channel effect, has a significantly low short channel effect in comparison with the existing bulk structure. However, a floating body effect in which control of the leakage current or a critical (threshold) voltage in the semiconductor device becomes very difficult due to variation in the leakage current or the critical (threshold) voltage since the electric potential of the junction region in which the silicon channel 11 is formed is floated, a self-heating effect, and so on are generated. Furthermore, the SOI-structure MOSFET does not have a characteristic in which it can control the threshold voltage through control of the substrate bias, which was a significant advantage of the bulk structure.

As an alternative to mitigate problems of the SOI structure, a MOSFET of the SON(Silicon-On-Nothing) structure has been proposed, following the SOI. The SON MOSFET has been proposed by taking notice of the facts that the relative dielectric constant of an insulating film became 1 (i.e., the lowest relative dielectric constant) and the performance of semiconductor devices would become the best as the relative dielectric constant became the lowest. Therefore, to improve the performance of semiconductor devices, an air layer is formed under a silicon layer forming a channel.

Strained-Si technology has been introduced in order to improve the performance of semiconductor devices and power efficiency along with the SOI or SON structure. Strained-Si technology is a design technique in which atoms of silicon for forming semiconductor devices are forcedly separated from one another. If atoms are separated from other atoms, electrons can move further fast in the same power level. This results in an improved performance of semiconductor devices.

An reference document on the SON MOSFET is as follows:

Malgorzata Jurczak et. al., “Silicon-On-Nothing (SON)—an innovative Process for Advanced CMOS”, IEEE Transactions on Electron Devices, Vol. 47, No. 11, pp. 2179-2187, 2000

The related art SON MOSFET, however, has a structure in which the bottom of the channel is not fully separated by the air layer, but a “nothing” region is filled with the insulating film in a subsequent process. A process is also complicated.

To solve the above-mentioned problems, the present invention proposes a SON MOSFET in which a process is simple while having the advantages of both the SOI-structure MOSFET and the bulk-structure MOSFET in the related art.

### SUMMARY OF THE INVENTION

It is an object of the present invention to provide a SON MOSFET in which blisters are formed within a silicon substrate, so that a threshold voltage can be controlled by applying a voltage to the silicon substrate as in the bulk structure and the floating body effect and the self-heating effect, which are the biggest problems of the SOI structure, can be prohibited.

It is another object of the present invention to provide a SON MOSFET in which a blister (i.e., air layers) having a more excellent insulating characteristic than that of the insulating film used in the SOI structure is formed in a lower region of a silicon channel, thus maximizing the advantages of the SOI structure.

It is further another object of the present invention to provide a SON MOSFET in which a gate voltage can control the electric potential of a channel more effectively and the path of a bulk punchthrough current can be shielded, due to a blister formed in a lower region of a silicon channel, so that the short channel effect can be significantly improved.

It is further another object of the present invention to provide a SON MOSFET in which a blister formed in a lower region of a silicon channel applies tensile stress to the silicon channel like a field effect transistor fabricated using strained-Si in the related art, thus improving the mobility of electrons and holes that are moved along the silicon channel and enabling an ultra-high speed operation.

It is further another object of the present invention to provide a SON MOSFET in which through a new inventive structure, a manufacturing process can be simplified, a device characteristic such as reproduction (reproducibility) can be improved, the limitation of device scaling can be overcome and ultra-high speed/ultra-high integration are made possible.

It is further another object of the present invention to provide a SON MOSFET in which blisters formed in a lower region of a source/drain reduce a junction leakage current and junction capacitance, increase a junction breakdown voltage and serve as stoppers to prevent a punchthrough leakage current, thereby implementing low-power devices, improving a reliability characteristic and accomplishing miniaturization of devices.

A SON MOS transistor according to an embodiment of the present invention comprises isolation insulating films formed at both upper sides of a silicon substrate, a gate insulating film and a gate electrode that are sequentially formed on a surface of the silicon substrate between the isolation insulating films, a source region and a drain region that are formed on the silicon substrate between the gate insulating film and the isolation insulating films, a blister formed within the silicon substrate under the gate insulating film, and a silicon channel, which is surrounded by the blister, the source region and the drain region, within the silicon substrate. The blister is formed of hydrogen or helium ion.

The SON MOS transistor according to an embodiment of the present invention may further comprise blisters formed within the silicon substrate under the source region or the drain region.

A SON MOS transistor according to another embodiment of the present invention comprises a source region and a drain region formed at both upper sides of a silicon substrate, screen oxide films formed to cover the source region and the drain region, a blister formed within the silicon substrate between the screen oxide films, a silicon channel, which is located on the blister and has both sides adjacent to the source region and the drain region, respectively, and a gate insulating film and a gate electrode that are sequentially formed on the silicon channel. The blister is formed of hydrogen or helium ion.

In the SON MOS transistor according to an embodiment and another embodiment of the present invention, the blister may have a relative dielectric constant of 1.

A method of manufacturing a SON MOS transistor according to an embodiment of the present invention comprises the steps of (a) forming isolation insulating films at both upper sides of a silicon substrate, (b) sequentially forming a gate insulating film and a gate electrode on a surface of the silicon substrate between the isolation insulating films, (c) forming a source region and a drain region on the silicon substrate between the gate insulating film and the isolation insulating films, and (d) forming a blister within the silicon substrate under the gate insulating film, and forming a silicon channel, which is surrounded by the blister, the source region and the drain region, within the silicon substrate. The blister is formed of hydrogen or helium ion.

In the method of manufacturing the SON MOS transistor according to an embodiment of the present invention, in the step (d), the blister may be formed by implanting the hydrogen or helium ion into the silicon substrate located under the gate insulating film and then performing annealing.

In the method of manufacturing the SON MOS transistor according to an embodiment of the present invention, in the step (d), blisters may be further formed under the source region or the drain region.

In the method of manufacturing the SON MOS transistor according to an embodiment of the present invention, in the step (c), after the source region and the drain region are formed, a silicon nitride film may be formed to cover the isolation insulating films, the gate electrode, the source region and the drain region, wherein the silicon nitride film serves a stopper to prevent gas from being out-diffused from the blister formed within the silicon substrate in the step (d). In the step (d), after the blister and the silicon channel are formed, the formed silicon nitride film may be removed.

A method of manufacturing a SON MOS transistor according to another embodiment of the present invention comprises the steps of (a) forming a source region and a drain region at both upper sides of a silicon substrate, (b) forming screen oxide films to cover the source region and the drain region, (c) forming a blister within the silicon substrate between the screen oxide films, and forming a silicon channel having both sides adjacent to the source region and the drain region, respectively, on the blister, and (d) sequentially forming a gate insulating film and a gate electrode on the silicon channel. The blister is formed of hydrogen or helium ion.

In the method of manufacturing the SON MOS transistor according to another embodiment of the present invention, in the step (c), the blister may be formed by implanting the hydrogen or helium ion into the silicon substrate between the screen oxide films and then performing annealing.

In the method of manufacturing the SON MOS transistor according to another embodiment of the present invention, in the step (c), the hydrogen or helium ion forming the blister may have its implant depth controlled according to a step occurring between the screen oxide films and a pseudo gate electrode formed on the silicon substrate between the screen oxide films, whereby the hydrogen or helium ion is selectively implanted into the silicon substrate between the screen oxide films.

In the method of manufacturing the SON MOS transistor according to another embodiment of the present invention, in the step (a), a sacrificial insulating film and a pseudo gate electrode may be sequentially formed on a surface of the silicon substrate between the source region and the drain region, and the source region and the drain region are formed using the pseudo gate electrode as a mask. In the step (c), after the blister and the silicon channel are formed, the pseudo gate electrode and the sacrificial insulating film may be sequentially etched.

In the method of manufacturing the SON MOS transistor according to another embodiment of the present invention, the isolation insulating films or the screen oxide films may be formed by an oxidization (oxidation) process or a Chemical Vapor Deposition (CVD) process.

In the method of manufacturing the SON MOS transistor according to an embodiment and another embodiment of the present invention, the location or depth of the hydrogen or helium ion implanted into the silicon substrate may be controlled by controlling implant energy.

In the method of manufacturing the SON MOS transistor according to an embodiment and another embodiment of the present invention, an annealing temperature, which is performed so that the hydrogen or helium ion implanted into the silicon substrate forms the blister, may be set in the range of 400° C. to 800° C.

### BRIEF DESCRIPTION OF THE DRAWINGS

FIG. 1 is a cross-sectional view of a SOI MOSFET in the related art;

FIG. 2 is a cross-sectional view of a SON MOSFET according to an embodiment of the present invention;

FIG. 3 is a process flowchart illustrating a method of manufacturing a SON MOSFET according to an embodiment of the present invention;

FIGS. 4 to 7 are cross-sectional views illustrating respective steps of a method of manufacturing a SON MOSFET according to an embodiment of the present invention;

FIG. 8 is a cross-sectional view of a SON MOSFET according to another embodiment of the present invention;

FIG. 9 is a process flowchart illustrating a method of manufacturing a SON MOSFET according to another embodiment of the present invention; and

FIGS. 10 to 16 are cross-sectional views illustrating respective steps of a method of manufacturing a SON MOSFET according to another embodiment of the present invention.

### DETAILED DESCRIPTION OF PREFERRED EMBODIMENTS

The present invention will now be described in connection with preferred embodiments with reference to the accompanying drawings.

A SON MOSFET according to an embodiment of the present invention will be described below with reference to FIG. 2. FIG. 2 is a cross-sectional view of a SON MOSFET according to an embodiment of the present invention.

Referring to FIG. 2, the SON MOSFET according to an embodiment of the present invention comprises a silicon substrate 100, isolation insulating films 110, a gate insulating film 120, a gate electrode 130, a source region 140, a drain region 141, blister 150, 151 and a silicon channel 101.

The isolation insulating films 110 are formed at both upper sides of the silicon substrate 100. The gate insulating film 120 and the gate electrode 130 are sequentially stacked on a surface of the silicon substrate 100, which is located between the isolation insulating films 110. The isolation insulating films 110 function to electrically isolate respective unit elements (e.g., MOS transistors, etc.), and are formed of oxide deep into the silicon substrate 100 using a Local Oxidation of Silicon (LOCOS) process or a trench process.

Furthermore, the source region 140 and the drain region 141 are formed on the silicon substrate 100 located between the gate insulating film 120 and the isolation insulating films 110. The blister 150 is formed in an internal region of the silicon substrate 100, which is located under the gate insulating film 120. The internal region of the silicon substrate 100, which is surrounded by the blister 150, the source region 140 and the drain region 141, is defined as a silicon channel 101. The blisters 151 can be further formed in an internal region of the silicon substrate 100, which is located under the source region 140 or the drain region 141. The blisters 150, 151 are formed of hydrogen or helium ion and can have a relative dielectric constant of 1.

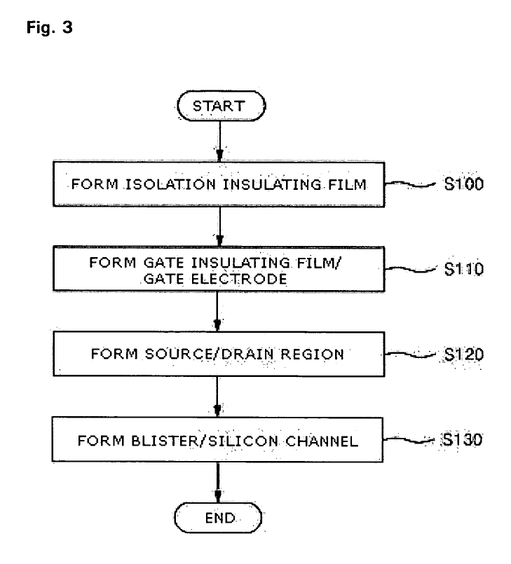

A method of manufacturing the SON MOSFET according to an embodiment of the present invention will be described below with reference to FIGS. 3 to 7.

FIG. 3 is a process flowchart illustrating a method of manufacturing a SON MOSFET according to an embodiment of the present invention.

The isolation insulating films 110 are formed at both upper sides of the silicon substrate 100 at step S100. The gate insulating film 120 and the gate electrode 130 are sequentially stacked on a surface of the silicon substrate 100 between the isolation insulating films 110 at step S110. The isolation insulating films 110 can be formed using an oxidization (oxidation) process or a Chemical Vapor Deposition (CVD) process.

The source region 140 and the drain region 141 are then formed on the silicon substrate 100 between the gate insulating film 120 and the isolation insulating films 110, respectively, at step S120. The source region 140 and the drain region 141 can be formed by performing an ion implant (I2 P)process and then diffusing the ion through a RTA(Rapid Thermal Annealing) process.

Thereafter, the blister 150 is formed in the internal region of the silicon substrate 100, which is located under the gate insulating film 120. As the blister 150 is formed, the internal region of the silicon substrate 100, which is surrounded by the blister 150, the source region 140 and the drain region 141, is defined as the silicon channel 101 at step S130. At this time, the blisters 151 can be further formed in the internal region of the silicon substrate 100 below the source region 140 and the drain region 141, respectively. Each of the blisters 150, 151 can be formed of hydrogen or helium ion and can have a relative dielectric constant of 1.

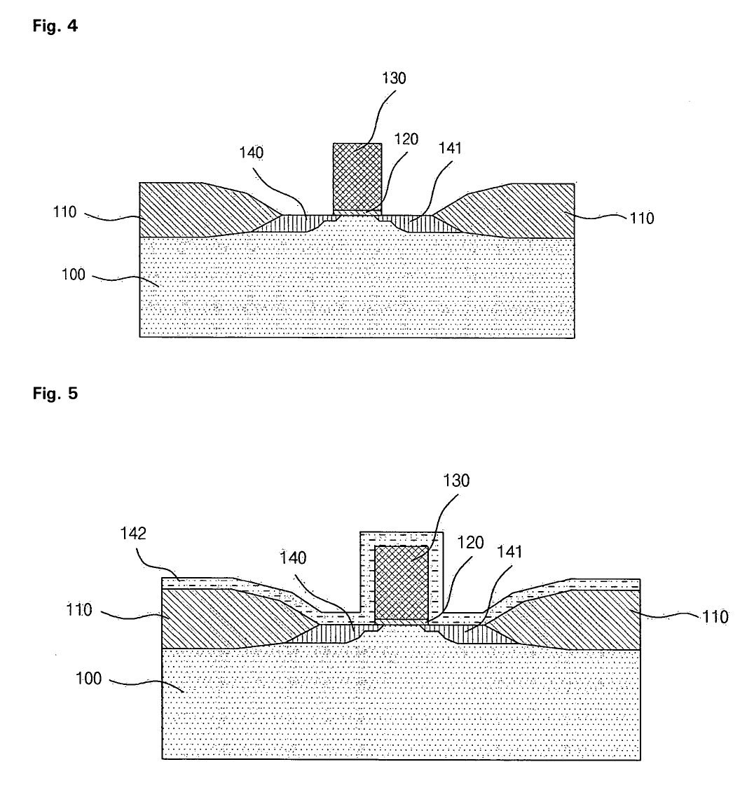

FIGS. 4 to 7 are cross-sectional views illustrating the respective steps of the method of manufacturing the SON MOSFET according to an embodiment of the present invention, and show cross-sectional view of the respective steps of FIG. 3.

FIG. 4 is a cross-sectional view of the SON MOSFET in which the isolation insulating films 110, the gate insulating film 120 and the gate electrode 130, the source region 140 and the drain region 141 are formed on the silicon substrate 100 through the steps S100 to S120. In more detail, the isolation insulating films 110 are formed on the silicon substrate 100. The gate insulating film 120 and the gate electrode 130 are formed on the silicon substrate 100. The source region 140 and the drain region 141 are then formed through an ion implant process and a RTA process.

FIGS. 5 to 7 show variation in the cross section of the step S130 for forming the blister 150 in the silicon substrate 100, and show sub-divided steps of the step S130.

The blister 150 can be formed by implanting hydrogen (H) or helium (He) ion into the internal region of the silicon substrate 100, which is located under the gate insulating film 120, and then performing annealing. In the process of forming the blister 150, a silicon nitride (SiN) film 142 can be utilized.

This will be described in more detail below.

Referring first to FIG. 5, the silicon nitride film 142 is formed on the entire surface of the silicon substrate 100 so that it covers the isolation insulating films 110, the gate electrode 130, the source region 140 and the drain region 141. The silicon nitride film 142 serves as a stopper to prevent hydrogen or helium from being out-diffused from the blister 150, 151 formed in the silicon substrate 100 after the hydrogen or helium ion is implanted in a subsequent process.

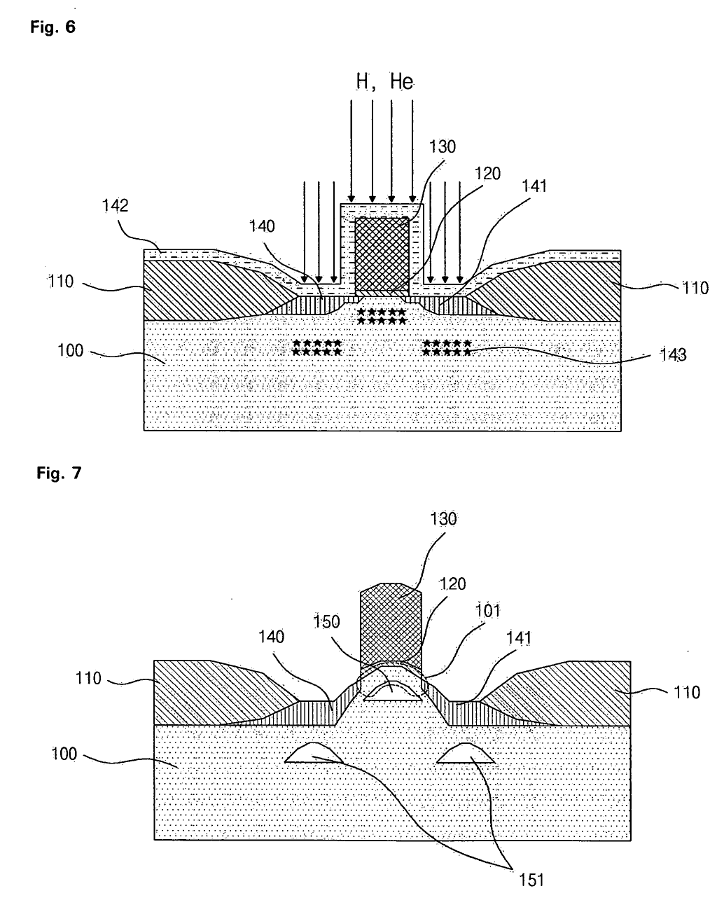

Referring next to FIG. 6, hydrogen or helium ion 143 is implanted into the internal region of the silicon substrate 100, which is located under the gate insulating film 120. The hydrogen or helium ion 143 can be implanted in a direction vertical to the top surface of the silicon nitride film 142. A location or depth of the hydrogen or helium ion 143 implanted into the silicon substrate 100 can be decided through control of implant energy.

Referring to FIG. 7, an annealing process such as RTA is performed so that the hydrogen or helium ion 143 implanted into the silicon substrate 100 forms the blister 150. At this time, the relative dielectric constant of the blister 150 can be 1. A temperature, which causes the hydrogen or helium ion 143 implanted into the silicon substrate 100 to form the blister 150, can be set in the range of 400° C. to 800° C.

As the blister 150 is formed, the internal region of the silicon substrate 100, which is surrounded by the blister 150, the source region 140 and the drain region 141, is defined as the silicon channel 101. The silicon nitride film 142 is then removed through a subsequent process such as wet etch.

In the structure constructed above, the blister 150 applies tensile stress to the silicon channel 101. As tensile stress is applied, the mobility of electrons and holes is improved as in the case where strained-Si is used, so that the drain current is increased when a device is turned on. That is, in the present invention, the blister 150 applies tensile stress to the silicon channel 101 to increase the mobility of electrons and holes, in the same manner as that in a MOSFET fabricated using strained-Si, strained-Si applies tensile stress to a channel to increase the mobility of electrons and holes.

Meanwhile, in the present embodiment, as shown in FIG. 6, the hydrogen or helium ion 143 can also be implanted into the region under the source region 140 or the drain region 141 and then annealed. Therefore, the blister 151 can be additionally formed in the internal region of the silicon substrate 100, which is located under the source region 140 or the drain region 141, as shown in FIG. 7.

As shown in FIG. 6, the isolation insulating films 110 are thickly formed in the field region of the device. Therefore, in the ion implant process, the hydrogen ion 143 or helium ion 143 gathers (exists) only in the silicon substrate 100 under the gate electrode 130, or the source region 140 and the drain region 141.

The depth of the hydrogen or helium ion 143, which is implanted into the silicon substrate 100, can be varied due to a step between the gate electrode 130 and the source region 140 and between the gate electrode 130 and the drain region 141.

The blisters 151 existing under the source region 140 and the drain region 141 function to reduce the junction leakage current and the junction capacitance, implementing low-power devices, and also to increase the junction breakdown voltage, improving a reliability characteristic. The blisters 151 serve as a stopper to prevent a punchthrough leakage current, thus enabling miniaturization of devices. Furthermore, since it is unnecessary to use a punchthrough stopper formed using an additional implant process, the production cost can be saved.

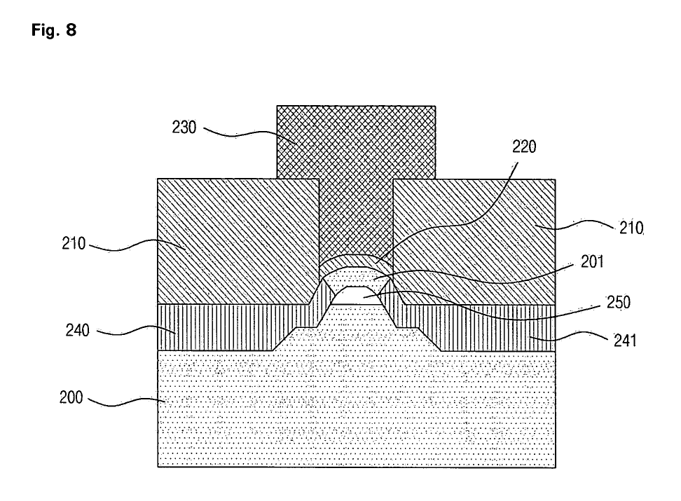

FIG. 8 is a cross-sectional view of a SON MOSFET according to another embodiment of the present invention.

Referring to FIG. 8, the SON MOSFET according to another embodiment of the present invention comprises a silicon substrate 200, a source region 240, a drain region 241, screen oxide films 210, a blister 250, a silicon channel 201, a gate insulating film 220 and a gate electrode 230.

The present embodiment is different from the above-described embodiment in that the blister 250 is formed only below the silicon channel 201.

The source region 240 and the drain region 241 are formed at both sides of the silicon substrate 200. The screen oxide films 210 covering the source region 240 and the drain region 241, respectively, are formed on the source region 240 and the drain region 241, respectively, with them being spaced apart from each other. The blister 250 is formed in an internal region of the silicon substrate 200, which is located between the screen oxide films 210.

The screen oxide films 210 are formed on the source region 240 and the drain region 241, respectively, in a subsequent process, and function to prevent hydrogen or helium ion 204 from being implanting into the silicon substrate 200 below the source region 240 and the drain region 241.

The silicon channel 201 is formed on the blister 250 and has both sides being adjacent to the source region 240 and the drain region 241, respectively. The gate insulating film 220 and the gate electrode 230 are sequentially formed on the silicon channel 201. The blister 250 can be formed of hydrogen or helium ion 204 and can have a relative dielectric constant of 1.

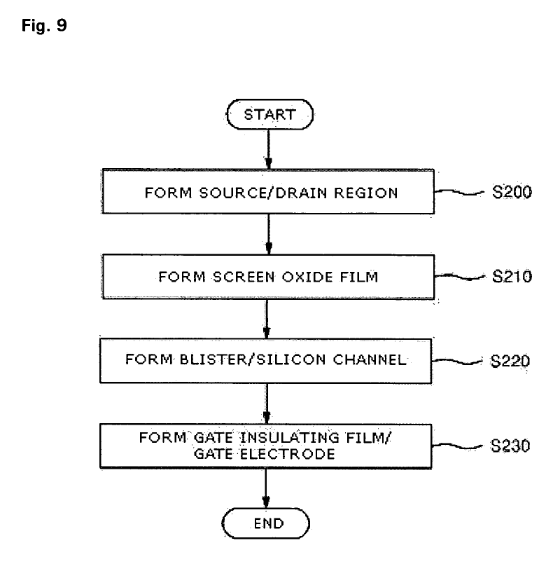

A method of manufacturing the SON MOSFET according to another embodiment of the present invention will be described below with reference to FIGS. 9 to 16.

FIG. 9 is a process flowchart illustrating a method of manufacturing a SON MOSFET according to another embodiment of the present invention.

The source region 240 and the drain region 241 are formed at both upper sides of the silicon substrate 200 at step S200. The screen oxide films 210 covering the source region 240 and the drain region 241 are formed at step S210. The screen oxide films 210 can be formed by an oxidization (oxidation) process or a CVD process. The source region 240 and the drain region 241 can be formed by performing an ion implant process and then diffusing the ion through a RTA process.

Thereafter, the blister 250 is formed in the internal region of the silicon substrate 200, which is located between the screen oxide films 210. As the blister 250 is formed, the internal region of the silicon substrate 200, which is located on the blister 250, is defined as the silicon channel 201 at step S220. The blister 250 can be formed of the hydrogen or helium ion 204. Both sides of the silicon channel 201 are adjacent to the source region 240 and the drain region 241, respectively.

Thereafter, the gate insulating film 220 and the gate electrode 230 are sequentially stacked on the silicon channel 201 at step S230.

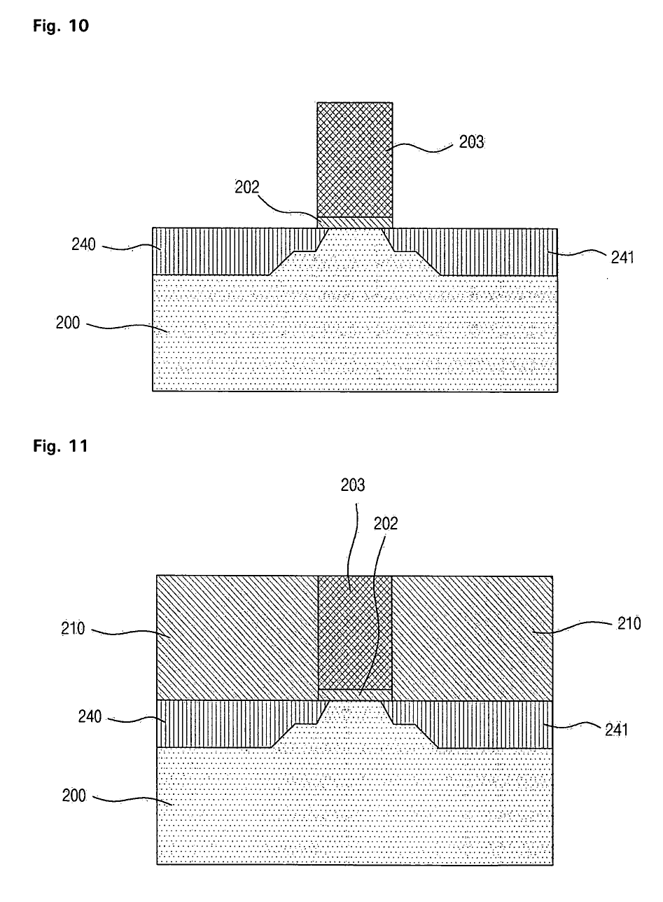

FIGS. 10 to 16 are cross-sectional views illustrating respective steps of a method of manufacturing a SON MOSFET according to another embodiment of the present invention, and are cross-sectional views of the respective steps of FIG. 9.

The blister 250 can be formed by implanting the hydrogen or helium ion 204 into the internal region of the silicon substrate 200 between the screen oxide films 210 and then performing annealing. In the process of forming the blister 250, a pseudo gate electrode 203 shown in FIGS. 10 to 13 can be utilized.

FIG. 10 is a cross-sectional view of the SON MOSFET at the step S200 for forming the source region 240 and the drain region 241 on the silicon substrate 200.

At step S200, as shown in FIG. 10, a sacrificial insulating film 202 and the pseudo gate electrode 203 are sequentially formed on a surface of the silicon substrate 200 between the source region 240 and the drain region 241. The source region 240 and the drain region 241 are formed using the sacrificial insulating film 202 and the pseudo gate electrode 203 as a mask.

FIG. 11 is a cross-sectional view of the SON MOSFET at the step S210 for forming the screen oxide films 210.

At step S210, as shown in FIG. 11, the screen oxide films 210 are formed at both sides of the sacrificial insulating film 202 and the pseudo gate electrode 203. In more detail, the screen oxide films 210 is formed in such a manner that the screen oxide films 210 is deposited on the structure formed through the process of FIG. 10 and the height of the deposited screen oxide films 210 is polished through a Chemical Mechanical Polishing (CMP) process. The screen oxide films 210 function to prevent the hydrogen or helium ion 204 from being implanted into other parts of the silicon substrate 200 when the hydrogen or helium ion 204 is implanted into the silicon substrate 200 through an ion implant process (i.e., a subsequent process). Therefore, the screen oxide films 210 serves as a stopper to limit the implant location of the hydrogen or helium ion 204 to the inside of the silicon substrate 200 located under the silicon channel 201.

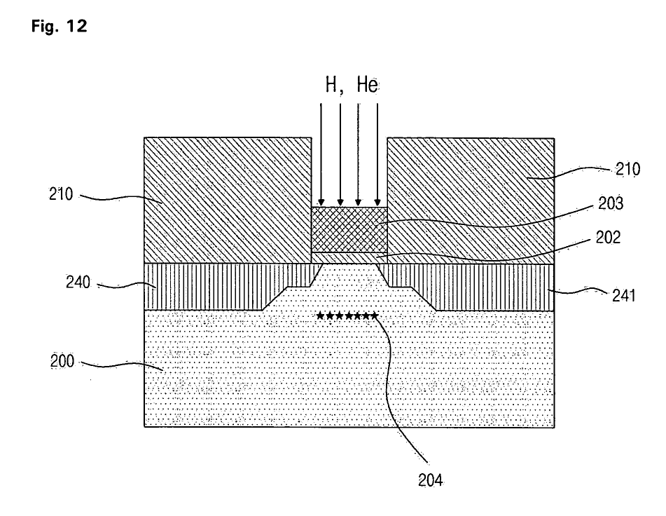

FIGS. 12 to 14 show variation in the cross section of the step S220 for forming the blister 250 in the silicon substrate 200, and show sub-divided steps of the step S220.

As shown in FIG. 12, the hydrogen or helium ion 204 is implanted into a top surface of the pseudo gate electrode 203 and is thus implanted into the silicon substrate 200 between the screen oxide films 210. In this case, a step is generated between the screen oxide films 210 and the pseudo gate electrode 203. The hydrogen or helium ion 204 can be selectively implanted into the silicon substrate 200 between the screen oxide films 210 by controlling the implant depth of the hydrogen or helium ion 204 according to the generated step. To cause the step to be generated between the screen oxide films 210 and the pseudo gate electrode 203, the pseudo gate electrode 203 can be selectively etched downwardly through Reactive Ion Etching (RIE), wet etch or the like.

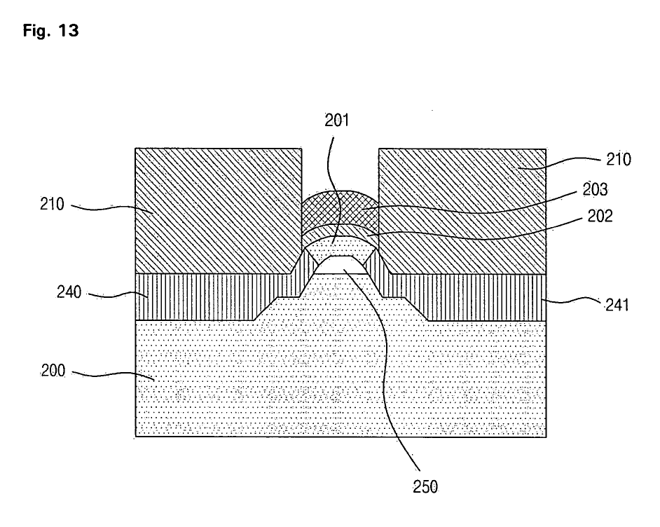

An annealing process is then performed so that the hydrogen or helium ion 204 implanted into the silicon substrate 200 forms the blister 250, as shown in FIG. 13. As the blister 250 is formed, the internal region of the silicon substrate 200, which is located on the blister 250, is defined as the silicon channel 201. Both sides of the defined silicon channel 201 are adjacent to the source region 240 and the drain region 241, respectively.

In this case, the volume of the hydrogen or helium ion 204 (i.e., the air layer) is increased while the blister 250 is formed through the annealing process. This makes the silicon channel 201, the sacrificial insulating film 202 and the pseudo gate electrode 203 bent in a convex form.

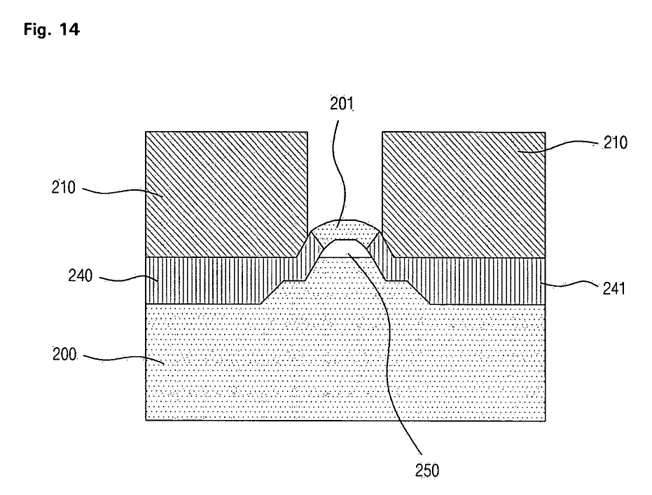

Thereafter, as shown in FIG. 14, the pseudo gate electrode 203 is etched through RIE, wet etch, etc. The sacrificial insulating film 202 is then etched. In the previous process, damage is applied to the film quality of the pseudo gate electrode 203 and the sacrificial insulating film 202 (The film quality of the pseudo gate electrode 203 and the sacrificial insulating film 202 is degraded by ion damages) while experiencing the ion implant process and the annealing process. For this reason, after both the pseudo gate electrode 203 and the sacrificial insulating film 202 are removed, the gate insulating film 220 and the gate electrode 230 are formed again in a subsequent process.

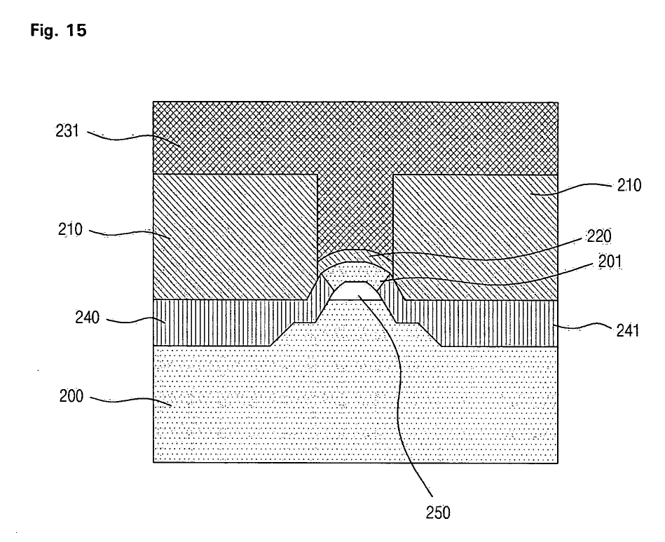

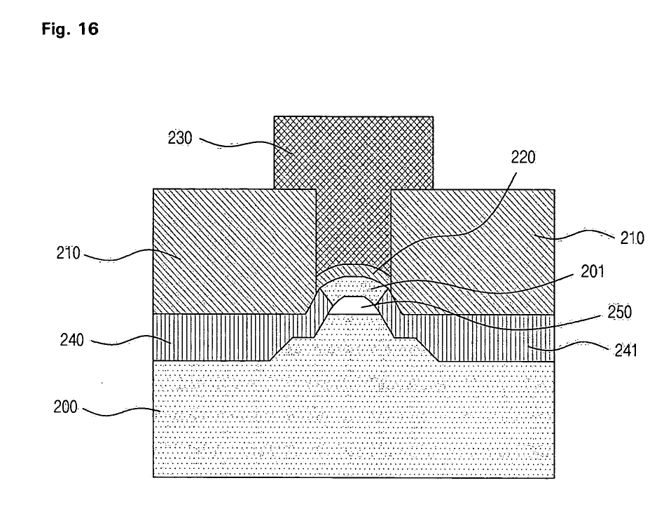

FIGS. 15 and 16 show sub-divided steps of the step S230.

After the pseudo gate electrode 203 and the sacrificial insulating film 202 are removed, the gate insulating film 220 and a gate electrode material 231 are sequentially stacked, as shown in FIG. 15. The deposited gate electrode material 231 is patterned to form the gate electrode 230 as shown in FIG. 16.

In accordance with an embodiment and another embodiment of the present invention, the blisters 150, 151 and 250 are formed within the silicon substrates 100, 200. Therefore, the advantages of both the SOI structure and the bulk structure can be obtained.

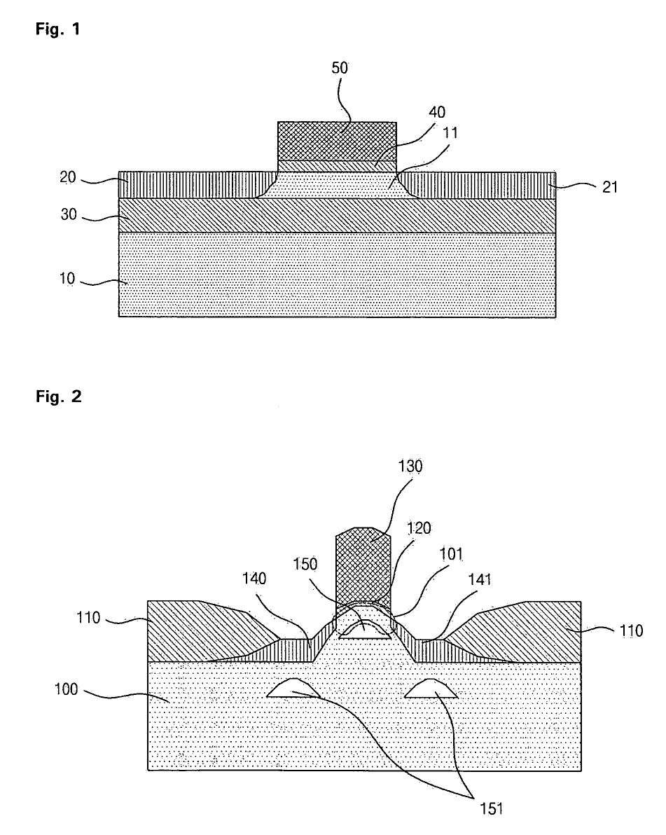

In general, the SOI structure in which the oxide film (SiO₂) having a relative dielectric constant of 3.9 is formed on the silicon substrate 10 as the substrate insulation film 30 as in FIG. 1 is stronger in punchthrough than the bulk structure, and has low junction capacitance of the junction region between the source/drain and the silicon channel 11 and a low leakage current when a device is turned off. Furthermore, the SOI structure is a thin body structure in comparison with the bulk structure. Therefore, the ability to control the electric potential of a channel of a gate voltage can be improved and the short channel effect can be also significantly reduced.

In the present invention, however, the blisters 150, 151 and 250 having a relative dielectric constant of 1, instead of the oxide film (SiO₂) having a relative dielectric constant of 3.9, are formed within the silicon substrates 100, 200 through hydrogen or helium ion implant. Therefore, the performance of the SOI structure can be maximized and device characteristics can be improved accordingly.

Furthermore, in the MOSFET of the SON structure, the silicon channels 101, 201 are connected to the silicon substrates 100, 200 unlike the SOI structure in which the silicon channel 11 is completely separated from the silicon substrate 10 by means of the substrate insulation film 30. Therefore, the floating body effect, the self-heating effect, and the like, which were the problems of the SOI structure, can be reduced, a threshold voltage can be controlled by a substrate bias, which is one of the biggest advantages of the bulk structure, and the design of ElectroStatic Discharge (ESD) circuits is made possible.

Furthermore, problems accompanied by miniaturization can be mitigated. Therefore, device miniaturization of sub-10 nm or less can be implemented, and ultra-high speed/ultra-high integration semiconductor devices, such as ultra-high integration memory chips of a terabit or higher and ultra-high speed logic circuit chips of 60 GHz or higher, can be implemented.

As described above, the SON MOSFETs according to an embodiment and another embodiment of the present invention have the following advantages.

First, a blister is formed within a silicon substrate. Therefore, a threshold voltage can be controlled by applying a voltage to the silicon substrate as in the bulk structure. Furthermore, the floating body effect and the self-heating effect, which are the biggest problems of the SOI structure, can be prohibited.

Second, a blister (i.e., an air layer) having a more excellent insulating characteristic than that of the insulating film used in the SOI structure is formed in a lower region of a silicon channel. It is thus possible to maximize the advantages of the SOI structure.

Third, the blister formed in the lower region of the silicon channel allows a gate voltage to control the electric potential of a channel more effectively and the passage of a bulk punchthrough current to be shielded, due to. Therefore, the short channel effect can be significantly improved.

Fourth, the blister formed in the lower region of the silicon channel applies tensile stress to the silicon channel like a field effect transistor fabricated using strained-Si in the related art. Therefore, the mobility of electrons and holes that are moved along the silicon channel can be enhanced and an ultra-high speed operation is made possible.

Fifth, through a new inventive structure, a manufacturing process can be simplified, device characteristics such as reappearance (reproducibility) can be improved, the limitation of device scaling can be overcome, and ultra-high speed/ultra-high integration are made possible.

Sixth, the blisters formed in the lower region of the source/drain reduce a junction leakage current and junction capacitance, increase a junction breakdown voltage and serve as stoppers to prevent a punchthrough leakage current. Therefore, low-power devices can be implemented, a reliability characteristic can be improved and devices can be miniaturized.

Therefore, the method of manufacturing the SON MOSFET according to an embodiment and another embodiment of the present invention can fabricate the above-mentioned SON MOSFET.

Although the foregoing description has been made with reference to the preferred embodiments, it is to be understood that changes and modifications of the present invention may be made by the ordinary skilled in the art without departing from the spirit and scope of the present invention and appended claims.

1. A Silicon-On-Nothing (SON) Metal Oxide Semiconductor Field Effect Transistor (MOSFET), comprising:
isolation insulating films formed at both upper sides of a silicon substrate;
a gate insulating film and a gate electrode that are sequentially formed on a surface of the silicon substrate between the isolation insulating films;
a source region and a drain region that are formed on the silicon substrate between the gate insulating film and the isolation insulating films;
a blister formed within the silicon substrate under the gate insulating film; and
a silicon channel, which is surrounded by the blister, the source region and the drain region, within the silicon substrate,
wherein the blister is formed of hydrogen or helium ion.

2. The SON MOSFET as claimed in claim 1, further comprising blisters formed within the silicon substrate under the source region or the drain region.

3. A SON MOSFET, comprising:
a source region and a drain region formed at both upper sides of a silicon substrate;
screen oxide films formed to cover the source region and the drain region;
a blister formed within the silicon substrate between the screen oxide films;
a silicon channel, which is located on the blister and has both sides adjacent to the source region and the drain region, respectively; and
a gate insulating film and a gate electrode that are sequentially formed on the silicon channel,
wherein the blister is formed of hydrogen or helium ion.

4. The SON MOSFET as claimed in claim 1, wherein the blister as a relative dielectric constant of 1.

5. A method of manufacturing of a SON MOSFET, comprising the steps of:
(a) forming isolation insulating films at both upper sides of a silicon substrate;
(b) sequentially forming a gate insulating film and a gate electrode on a surface of the silicon substrate between the isolation insulating films;
(c) forming a source region and a drain region on the silicon substrate between the gate insulating film and the isolation insulating films; and
(d) forming a blister within the silicon substrate under the gate insulating film, and forming a silicon channel, which is surrounded by the blister, the source region and the drain region, within the silicon substrate,
wherein the blister is formed of hydrogen or helium ion.

6. The method as claimed in claim 5, wherein in the step (d), the blister is formed by implanting the hydrogen or helium ion into the silicon substrate located under the gate insulating film and then performing annealing.

7. The method as claimed in claim 5, wherein in the step (d), blisters are further formed under the source region or the drain region.

8. The method as claimed in claim 5, wherein in the step (c), after the source region and the drain region are formed, a silicon nitride film is formed to cover the isolation insulating films, the gate electrode, the source region and the drain region, wherein the silicon nitride film serves a stopper to prevent gas from being out-diffused from the blister formed within the silicon substrate in the step (d), and
in the step (d), after the blister and the silicon channel are formed, the formed silicon nitride film is removed.

9. A method of manufacturing of a SON MOSFET, comprising the steps of:
(a) forming a source region and a drain region at both upper sides of a silicon substrate;
(b) forming screen oxide films to cover the source region and the drain region;
(c) forming a blister within the silicon substrate between the screen oxide films, and forming a silicon channel having both sides adjacent to the source region and the drain region, respectively, on the blister; and
(d) sequentially forming a gate insulating film and a gate electrode on the silicon channel,
wherein the blister is formed of hydrogen or helium ion.

10. The method as claimed in claim 9, wherein in the step (c), the blister is formed by implanting the hydrogen or helium ion into the silicon substrate between the screen oxide films and then performing annealing.

11. The method as claimed in claim 10, wherein in the step (c), the hydrogen or helium ion forming the blister has its implant depth controlled according to a step occurring between the screen oxide films and a pseudo gate electrode formed on the silicon substrate between the screen oxide films, whereby the hydrogen or helium ion is selectively implanted into the silicon substrate between the screen oxide films.

12. The method as claimed in claim 9, wherein in the step (a), a sacrificial insulating film and a pseudo gate electrode are sequentially formed on a surface of the silicon substrate between the source region and the drain region, and the source region and the drain region are formed using the pseudo gate electrode as a mask, and
in the step (c), after the blister and the silicon channel are formed, the pseudo gate electrode and the sacrificial insulating film are sequentially etched.

13. The method as claimed in claim 5, wherein the isolation insulating films or the screen oxide films are formed by an oxidization (oxidation) process or a Chemical Vapor Deposition (CVD) process.

14. The method as claimed in claim 6, wherein the location or depth of the hydrogen or helium ion implanted into the silicon substrate is controlled by controlling implant energy.

15. The method as claimed in claim 6, wherein an annealing temperature, which is performed so that the hydrogen or helium ion implanted into the silicon substrate forms the blister, is set in the range of 400° C. to 800° C.

16. The SON MOSFET as claimed in claim 3, wherein the blister as a relative dielectric constant of 1.

17. The method as claimed in claim 9, wherein the isolation insulating films or the screen oxide films are formed by an oxidization (oxidation) process or a Chemical Vapor Deposition (CVD) process.

18. The method as claimed in claim 10, wherein the location or depth of the hydrogen or helium ion implanted into the silicon substrate is controlled by controlling implant energy.

19. The method as claimed in claim 10, wherein an annealing temperature, which is performed so that the hydrogen or helium ion implanted into the silicon substrate forms the blister, is set in the range of 400° C. to 800° C.
